(19) United States
(12) Patent Application Publication
(10) Pub. No.: US 2014/0071739 A1
(43) Pub. Date: Mar. 13, 2014

(54) REFERENCE LEVEL ADJUSTMENT SCHEME

(71) Applicants: Jung Pill Kim, San Diego, CA (US); Taehyun Kim, San Diego, CA (US); Sungryul Kim, San Diego, CA (US); Xia Li, San Diego, CA (US)

(72) Inventors: Jung Pill Kim, San Diego, CA (US); Taehyun Kim, San Diego, CA (US); Sungryul Kim, San Diego, CA (US); Xia Li, San Diego, CA (US)

(73) Assignee: QUALCOMM Incorporated, San Diego, CA (US)

(21) Appl. No.: 13/613,100

(22) Filed: Sep. 13, 2012

(51) Int. Cl. G11C 11/16

(52) U.S. Cl. CPC G11C 11/1675
USPC 365/158

(57) ABSTRACT

A tunable reference cell scheme for magnetic random access memory (MRAM) circuitry selectively couples reference cells and data cells to shared write driver circuitry. Magnetic tunnel junctions (MTJs) in the reference cells can be programmed to a selected magnetic orientation using the shared write driver circuitry. The programmed reference cells can be merged with other programmed reference cells and/or with fixed reference cells to produce a tunable reference level for comparison with MTJ data cells during a read operation. Sharing write driver circuitry between data cells and reference cells allows programming of reference cells without consuming increased area on a chip or macro.

### TECHNICAL FIELD

The present disclosure generally relates to magnetic random access memory (MRAM) circuitry. More specifically, the present disclosure relates to tuning magnetic tunnel junction (MTJ) reference cells in MRAM circuitry.

### BACKGROUND

Unlike conventional random access memory (RAM) chip technologies, in magnetic RAM (MRAM) data is not stored as electric charge, but is instead stored by magnetic polarization of storage elements. The storage elements are formed from two ferromagnetic layers separated by a tunneling layer. One of the two ferromagnetic layers, which is referred to as the fixed layer or pinned layer, has a magnetization that is fixed in a particular direction. The other ferromagnetic magnetic layer, which is referred to as the free layer, has a magnetization direction that can be altered to represent either a “1” when the free layer magnetization is anti-parallel to the fixed layer magnetization or “0” when the free layer magnetization is parallel to the fixed layer magnetization or vice versa. One such device having a fixed layer, a tunneling layer, and a free layer is a magnetic tunnel junction (MTJ). The electrical resistance of an MTJ depends on whether the free layer magnetization and fixed layer magnetization are parallel or anti-parallel with each other. A memory device such as MRAM is built from an array of individually addressable MTJs.

To write data in a conventional MRAM, a write current, which exceeds a critical switching current, is applied through an MTJ. The write current exceeding the critical switching current is sufficient to change the magnetization direction of the free layer. When the write current flows in a first direction, the MTJ can be placed into or remain in a first state, in which its free layer magnetization direction and fixed layer magnetization direction are aligned in a parallel orientation. When the write current flows in a second direction, opposite to the first direction, the MTJ can be placed into or remain in a second state, in which its free layer magnetization and fixed layer magnetization are in an anti-parallel orientation.

To read data in a conventional MRAM, a read current may flow through the MTJ via the same current path used to write data in the MTJ. If the magnetizations of the MTJ's free layer and fixed layer are oriented parallel to each other, the MTJ presents a resistance that is different than the resistance the MTJ would present if the magnetizations of the free layer and the fixed layer were in an anti-parallel orientation. In a conventional MRAM, two distinct states are defined by two different resistances of an MTJ in a bitcell of the MRAM. The two different resistances represent a logic 0 and a logic 1 value stored by the MTJ.

To determine whether data in a conventional MRAM represents a logic 1 or a logic 0, the resistance of the MTJ in the bitcell is compared with a reference resistance. The reference resistance in conventional MRAM circuitry is a midpoint resistance between the resistance of an MTJ having a parallel magnetic orientation and an MTJ having an anti-parallel magnetic orientation. One way of generating a midpoint reference resistance is coupling in parallel an MTJ known to have a parallel magnetic orientation and an MTJ known to have an anti-parallel magnetic orientation.

Bitcells of a magnetic random access memory may be arranged in one or more arrays including a pattern of memory elements (e.g., MTJs in case of MRAM). STT-MRAM (Spin-Transfer-Torque Magnetic Random Access Memory) is an emerging nonvolatile memory that has advantages of non-volatility, comparable speed to eDRAM (Embedded Dynamic Random Access Memory), smaller chip size compared to eSRAM (Embedded Static Random Access Memory), unlimited read/write endurance, and low array leakage current.

### SUMMARY

According to aspects of the present disclosure, a memory apparatus includes a first magnetic tunnel junction (MTJ) reference cell coupled to a reference node, a first MTJ data cell coupled to a data node and sense circuitry coupled to the reference node and the data node. First write driver circuitry is coupled to an input data path of the first MTJ data cell. Switching circuitry is configured for selectively coupling the first MTJ reference cell and/or the first MTJ data cell to the first write driver circuitry.

Another aspect of the present disclosure includes a method for configuring magnetic random access memory (MRAM) circuitry. The method includes selectively coupling write driver circuitry to an MTJ reference cell in response to a reference select signal and applying a first write current to program at least one reference MTJ in the MTJ reference cell. The method also includes selectively coupling the write driver circuitry to a first MTJ data cell in response to a write select signal and applying a second write current to program at least one data MTJ in the first MTJ data cell.

Another aspect of the present disclosure includes an apparatus for configuring magnetic random access memory (MRAM) circuitry. The apparatus includes means for selectively coupling write driver circuitry to an MTJ reference cell in response to a reference select signal and means for applying a first write current to program at least one reference MTJ in the MTJ reference cell. The apparatus also includes means for selectively coupling the write driver circuitry to a first MTJ data cell in response to a write select signal and means for applying a second write current to program at least one data MTJ in the first MTJ data cell.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a circuit diagram of MRAM circuitry including a conventional reference cell read configuration.

FIG. 2 is a circuit diagram of MRAM circuitry including a conventional reference cell write configuration.

FIG. 3 is diagram illustrating tunable merged reference cell configurations.

FIG. 4 is a circuit diagram of MRAM circuitry including shared write driver circuitry according to an aspect of the present disclosure.

FIG. 5 is a circuit diagram of MRAM circuitry including shared write driver circuitry according to an aspect of the present disclosure.

FIG. 6 is a circuit diagram of MRAM circuitry including shared write driver circuitry according to an aspect of the present disclosure.

FIG. 7 is a circuit diagram of MRAM circuitry including shared write driver circuitry according to an aspect of the present disclosure.

FIG. 8 is a circuit diagram of MRAM circuitry including shared write driver circuitry according to an aspect of the present disclosure.

FIG. 9 is process flow diagram illustrating a method of configuring MRAM circuitry according to aspects of the present disclosure.

FIG. 10 is a block diagram showing an exemplary wireless communication system in which an configuration of the disclosure may be advantageously employed.

FIG. 11 is a block diagram illustrating a design workstation used for circuit, layout, and logic design of a semiconductor component according to one configuration.

### DETAILED DESCRIPTION

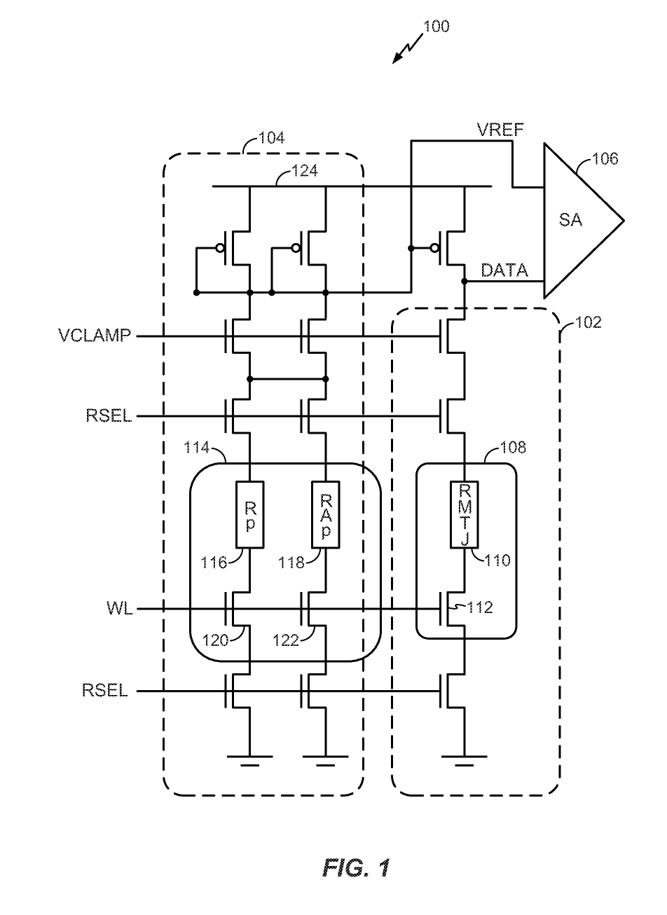

Referring to FIG. 1 a magnetic random access memory (MRAM) circuitry 100 includes data circuitry 102 and reference circuitry 104. The data circuitry 102 and reference circuitry 104 are coupled to sense amplifier circuitry 106. The data circuitry 102 includes an MRAM data cell 108 which includes a data cell magnetic tunnel junction (MTJ) 110 coupled to a data cell access transistor 112. The reference circuitry 104 includes an MRAM reference cell 114 that includes reference MTJs 116, 118 coupled to reference cell access transistors 120, 122. One of the reference MTJs 116 has a parallel magnetic orientation and the other reference MTJ 118 has an anti-parallel orientation.

When a read select signal (RSEL) is asserted, the reference MTJs 116, 118 are effectively coupled in parallel with each other. The MRAM reference cell 114 thereby generates a reference level (VREF) for comparison with a data level of the MRAM data cell 108. A read current flows on a bit line from a voltage source node 124 through the data cell MTJ 110 to generate the data level (DATA) input to the sense amplifier circuitry 106 and a reference current flows from the voltage source node 124 through the reference MTJs 116, 118 to generate the reference level (VREF) input to the sense amplifier circuitry 106. The data stored in the MRAM data cell 108 is output by the sense amplifier circuitry 106 based on a comparison of the reference level (VREF) with the data level (DATA). Transistors gated by a voltage clamp signal (VCLAMP) can hold the bit line at desired voltage level. A word line signal (WL) selects the data cell from a number of other data cells (not shown) that are coupled to the bit line.

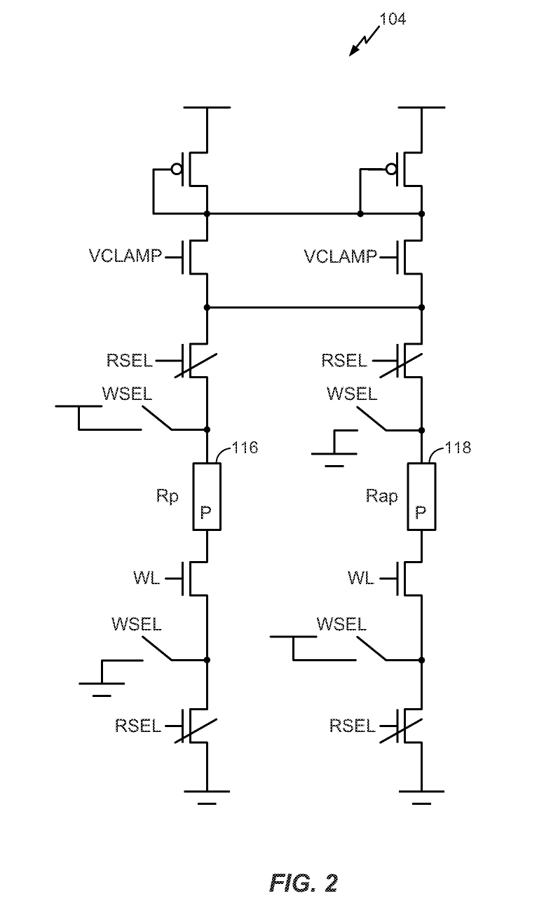

FIG. 2 is a circuit diagram of MRAM circuitry including a conventional reference cell write configuration. An MTJ write current is applied to each of the reference MTJs 116, 118 to configure the reference circuitry 104 so that one of the reference MTJs 116 is in a state of parallel magnetic orientation, and the other reference MTJ 118 is in a state of anti-parallel magnetic orientation. During the write operation, the RSEL signal is turned off and a write select signal (WSEL) is turned on. The write circuitry is configured so that write currents flow in opposite directions in the reference MTJs 116, 118. In general, one time write for the reference cell is sufficient to write to the reference MTJs if retention time of the write operation is within a specified predetermined range.

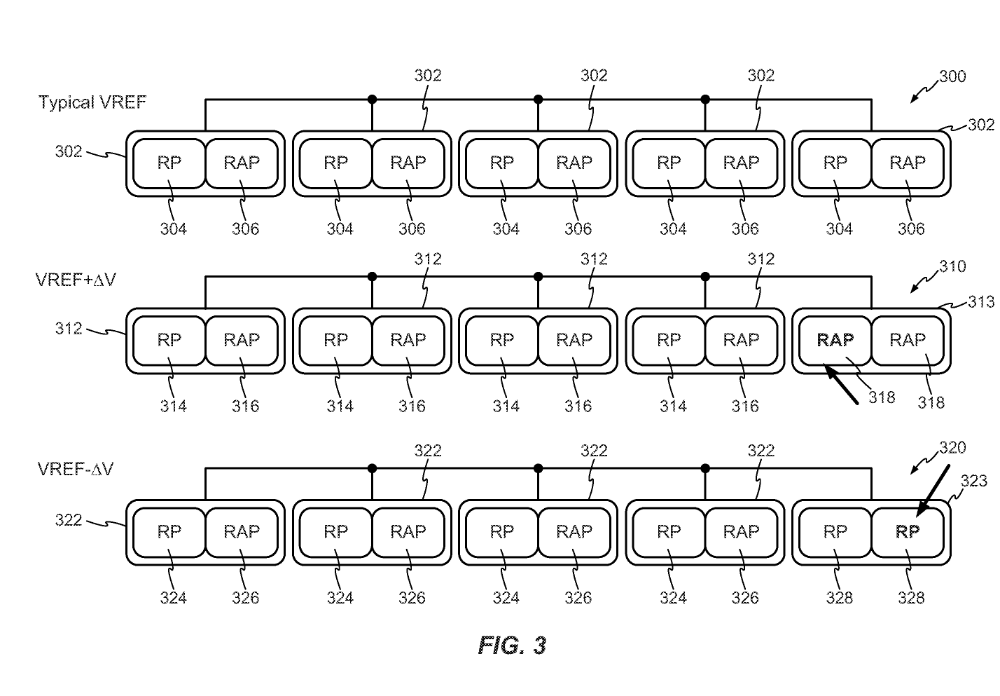

A reference level (VREF) can be generated by one reference cell as shown in FIGS. 1-2 or by multiple reference cells in a merged reference cell scheme as shown in FIG. 3, for example. In a merged reference cell scheme, merged reference cell circuitry combines a number of reference cell pairs. A first example of a merged reference cell scheme includes reference cell circuitry 300 in which a number of reference cell pairs 302 each include a reference cell having parallel magnetic orientation (RP state reference cell) 304 and a reference cell having anti-parallel magnetic orientation (RAP state reference cell) 306 to generate a typical reference level (VREF). The merged reference scheme improves yield due to improved statistical variation of the merged reference cells.

In a tunable merged reference cell scheme, the reference level of merged reference cells is adjusted by configuring both reference cells in one or more of the reference pairs in an RP state to decrease the reference level of merged cells or by configuring both reference cells in one or more reference pairs in an RAP state to increase the reference level of merged cells. A second example of a merged reference cell scheme includes tunable merged reference cell circuitry 310 in which a number of reference cell pairs 312 each include an RP state reference cell 314 and an RAP state reference cell 316. In this example, one reference cell pair 313 includes two RAP state reference cells 318 to produce an increased reference level (VREF+ΔV). A third example of a merged reference cell scheme includes tunable merged reference cell circuitry 320 in which a number of reference cell pairs 322 each include an RP state reference cell 324 and an RAP state reference cell 326. In this example, one reference cell pair 323 includes two RP state reference cells 328 to produce an decreased reference level (VREF−ΔV). Tunable merged reference schemes may be implemented using conventional MRAM data path configurations and conventional MRAM write driver circuitry to flexibly program reference levels without substantially increasing area on a chip.

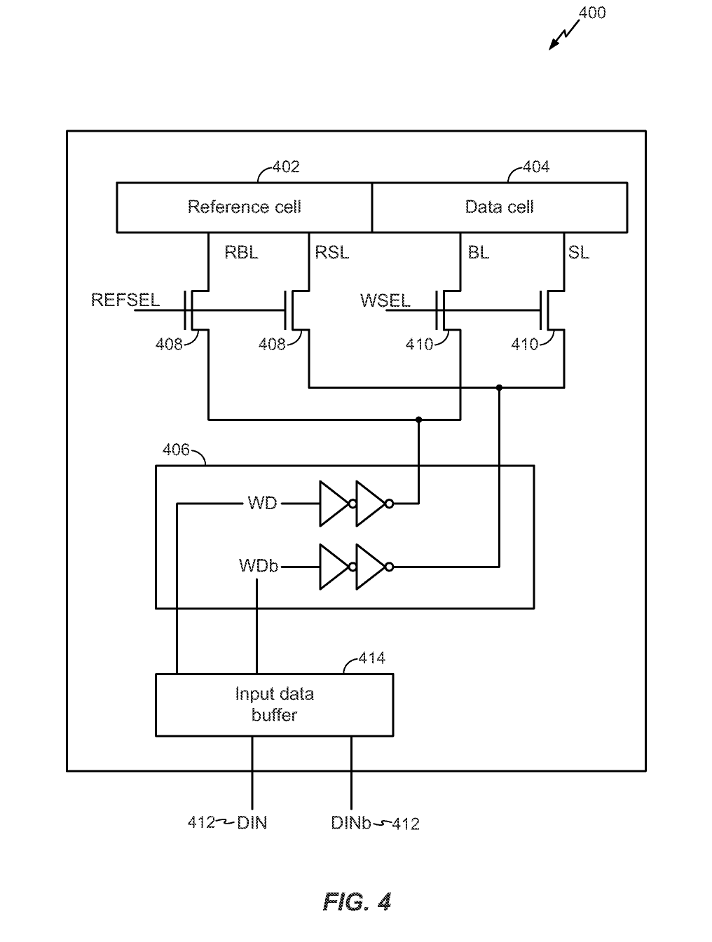

A tunable reference cell scheme according to an aspect of the present disclosure is described with reference to FIG. 4. MRAM circuitry 400 includes a reference cell 402, a data cell 404 and switching circuitry configured for selectively coupling the reference cell 402 and/or the data cell 404 to shared write driver circuitry 406. According to an aspect of the disclosure, the switching circuitry includes a pair of reference select transistors 408 coupled between the shared write driver circuitry 406 and the reference cell 402 and a pair of write select transistors 410 coupled between the shared write driver circuitry 406 and the data cell 404. A first reference cell bit line (REFSEL) is coupled to each of the reference select transistors 408. The shared write driver circuitry 406 may be coupled to an input data path including interface nodes 412 via input data buffer circuitry 414, for example.

The magnetic orientation of MTJs in the reference cell 402 is not fixed and can be programmed through the interface nodes 412, which may be coupled to external pins, for example. According to this aspect of the disclosure, the normal MRAM data path and write driver circuitry are shared for data cell write operations and reference cell write operations. Thus, the reference cell 402 can be tuned using the write driver circuitry 406 to VREF−ΔV or VREF+ΔV, as shown in FIG. 3.

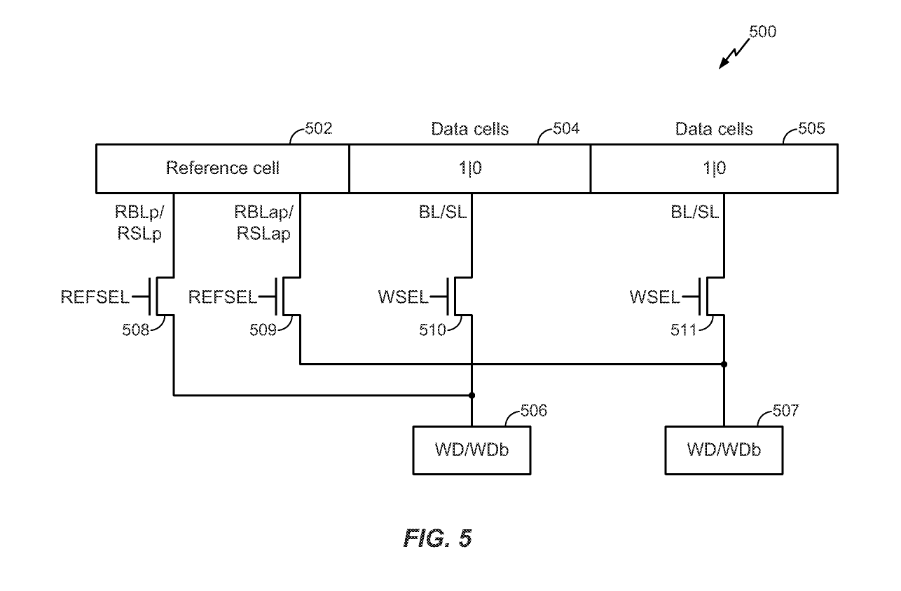

A tunable reference cell scheme according to another aspect of the present disclosure is described with reference to FIG. 5 in which one reference cell shares write circuitry with two or more data cells. Each separate write driver circuitry is shared amongst a reference cell and a data cell. MRAM circuitry 500 includes a reference cell 502, two or more data cells 504, 505 and switching circuitry configured for selectively coupling the reference cell 502 and/or the data cells 504, 505 to first shared write driver circuitry 506 and second shared write driver circuitry 507. According to this aspect of the disclosure, the switching circuitry includes a first reference select transistor 508 coupled between a first shared write driver circuitry 506 and the reference cell 502 and a second reference select transistor 509 coupled between a second shared write driver circuitry 507 and the reference cell 502. A first reference cell bit line (REFSEL) is coupled to each of the reference select transistors 508, 509. A first write select transistor 510 is coupled between the first shared write driver circuitry 506 and a first data cell 504 and a second write select transistor 511 is coupled between the second shared write driver circuitry 507 and a second data cell 505.

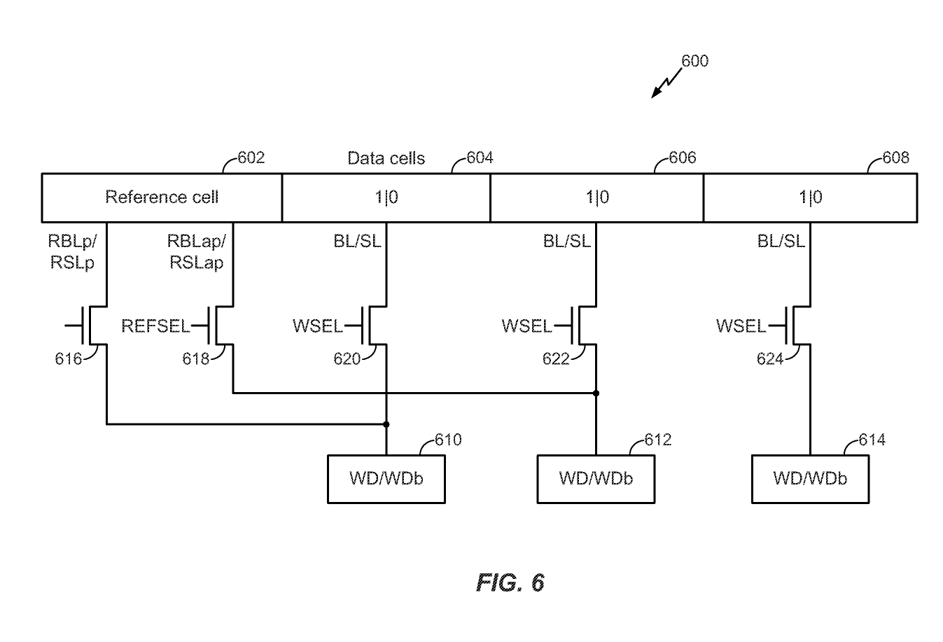

A tunable reference cell scheme according to another aspect of the present disclosure is described with reference to FIG. 6 in which one reference cell shares write circuitry with more than two data cells. For example, two of three write driver circuitries are shared between reference cell and two data cells. A third write driver circuitry is coupled to a data cell but not shared with a reference cell.

According to this aspect, MRAM circuitry 600 includes a reference cell 602, three data cells 604, 606, 608 and switching circuitry configured for selectively coupling the reference cell 602 and/or the data cells 604, 606, 608 to shared write driver circuitry 610, 612, 614. The switching circuitry includes a first reference select transistor 616 coupled between a first shared write driver circuitry 610 and the reference cell 602 and a second reference select transistor 618 coupled between a second shared write driver circuitry 612 and the reference cell 602. A first reference cell bit line (REFSEL) is coupled to the first reference select transistors 616 and the second reference select transistor 618. A first write select transistor 620 is coupled between the first shared write driver circuitry 610 and a first data cell 604 and a second write select transistor 622 is coupled between the second shared write driver circuitry 612 and a second data cell 606. According to this aspect, a third write select transistor 624 is coupled between a third write driver circuitry 614 and a third data cell 608. The third write driver circuitry 614 is not coupled to the reference cell 602.

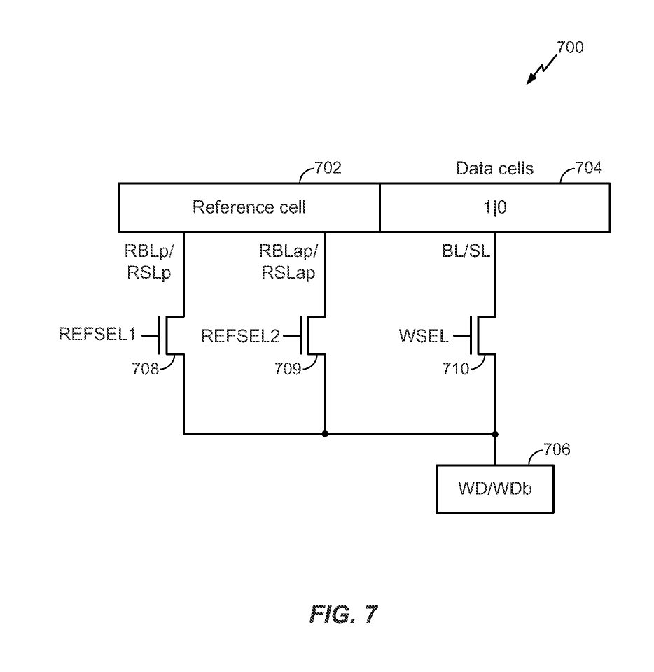

A tunable reference cell scheme according to another aspect of the present disclosure is described with reference to FIG. 7. MRAM circuitry 700 includes a reference cell 702, a data cell 704 and switching circuitry configured for selectively coupling the reference cell 702 and/or the data cell 704 to shared write driver circuitry 706. According to an aspect of the disclosure, the switching circuitry includes a pair of reference select transistors 708, 709 coupled between the shared write driver circuitry 706 and the reference cell 702 and a write select transistors 710 coupled between the shared write driver circuitry 706 and the data cell 704. A first reference cell bit line (REFSEL1) is coupled to one of the reference select transistors 708 and a second reference cell bit line (REFSEL2) is coupled to the other of the reference select transistors 709. According to this aspect of the disclosure, the normal MRAM data path and write driver circuitry are shared for data cell write operations and reference cell write operations. Because both reference select transistors 708, 709 are coupled to the same shared write driver circuitry 706, in this aspect, the first reference cell bitline (REFSEL1) controls a first reference MTJ (not shown) in the reference circuitry and the separate second reference cell bitline (REFSEL2) controls a second MTJ (not shown) in the reference circuitry.

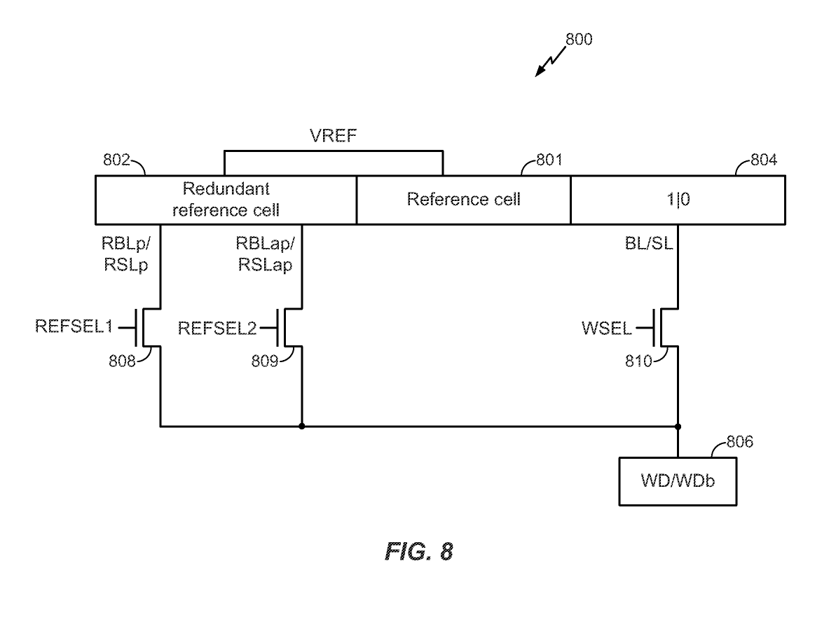

A tunable reference cell scheme according to another aspect of the present disclosure is described with reference to FIG. 8. MRAM circuitry 800 includes a fixed reference cell 801, a redundant tunable reference cell 802, a data cell 804 and switching circuitry configured for selectively coupling the tunable reference cell 802 and/or the data cell 804 to shared write driver circuitry 806. According to an aspect of the disclosure, the switching circuitry includes a pair of reference select transistors 808, 809 coupled between the shared write driver circuitry 806 and the tunable reference cell 802 and a write select transistor 810 coupled between the shared write driver circuitry 806 and the data cell 804. A first reference cell bit line (REFSEL1) is coupled to one of the reference select transistors 808 and a second reference cell bit line (REFSEL2) is coupled to the other of the reference select transistors 809. According to this aspect of the disclosure, the normal MRAM data path and write driver circuitry are shared for data cell write operations and tunable reference cell write operations. The fixed reference cell 801 and the tunable reference cell 802 are coupled together to produce a combined tuned reference level VREF−ΔV or VREF+ΔV, as shown in FIG. 3, for example. Because both reference select transistors 808, 809 are coupled to the same shared write driver circuitry 706, in this aspect, the first reference cell bitline (REFSEL1) controls a first reference MTJ (not shown) in the reference circuitry and the separate second reference cell bitline (REFSEL2) controls a second MTJ (not shown) in the reference circuitry.

An aspect of the present disclosure includes an apparatus for configuring magnetic random access memory (MRAM) circuitry. The apparatus includes means for selectively coupling write driver circuitry to an MTJ reference cell in response to a reference select signal and means for applying a first write current to program at least one reference MTJ in the MTJ reference cell. The means for selectively coupling write driver circuitry to an MTJ reference cell and means for applying a first write current to program at least one reference MTJ in the MTJ reference cell may include reference select transistors 808 and 809, for example. The apparatus also includes means for selectively coupling the write driver circuitry to a first MTJ data cell in response to a write select signal and means for applying a second write current to program at least one data MTJ in the first MTJ data cell. The means for selectively coupling the write driver circuitry to a first MTJ data cell and means for applying a second write current to program at least one data MTJ in the first MTJ data cell may include the write select transistor 810, for example.

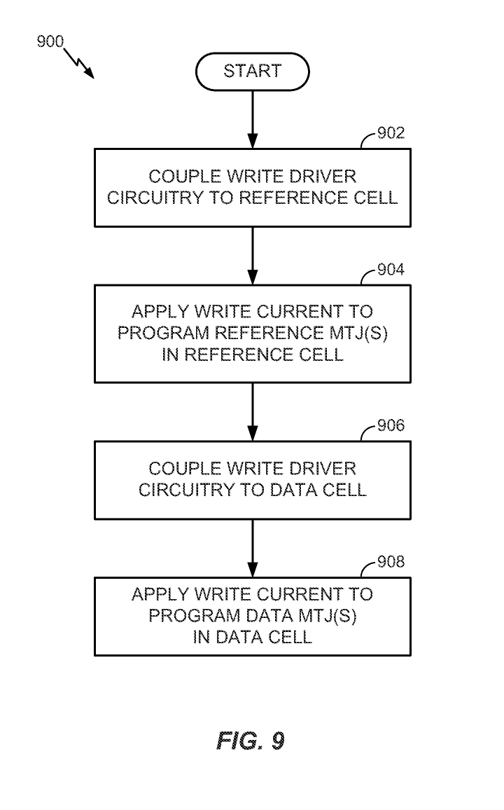

FIG. 9 is a process flow diagram illustrating a method for configuring magnetic random access memory (MRAM) circuitry according to aspects of the present disclosure. The method 900 includes selectively coupling write driver circuitry to an MTJ reference cell in response to a reference select signal in block 902. The method also includes applying a first write current to program at least one reference MTJ in the reference cell at block 904. According to one aspect of the present disclosure, the method also includes selectively coupling the write driver circuitry to an MTJ data cell in response to a write select signal in block 906 and applying a second write current to program at least one data MTJ in the data cell in block 908.

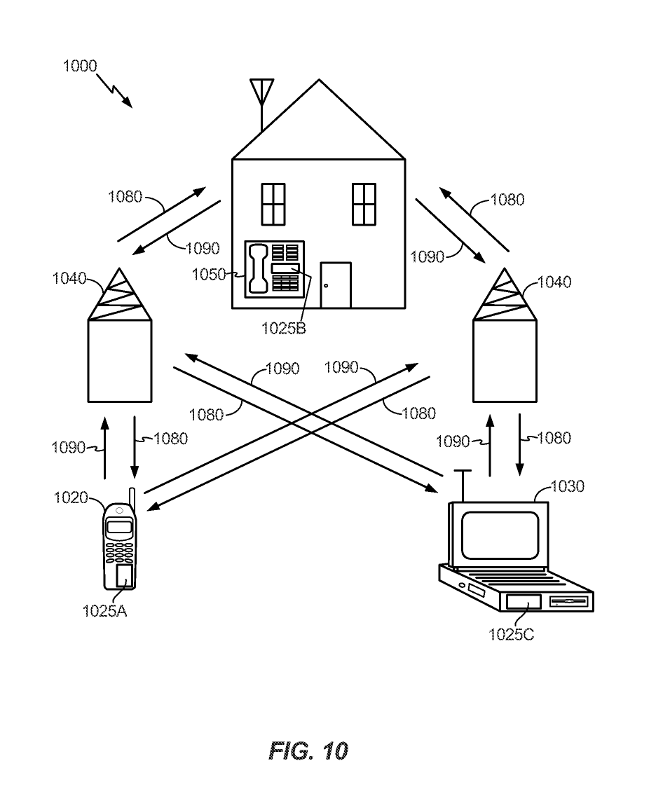

FIG. 10 is a block diagram showing an exemplary wireless communication system 1000 in which an aspect of the disclosure may be advantageously employed. For purposes of illustration, FIG. 10 shows three remote units 1020, 1030, and 1050 and two base stations 1040. It will be recognized that wireless communication systems may have many more remote units and base stations. Remote units 1020, 1030, and 1050 include IC devices 1025A, 1025C and 1025B that include the disclosed MRAM circuitry. It will be recognized that other devices may also include the disclosed MRAM circuitry, such as the base stations, switching devices, and network equipment. FIG. 10 shows forward link signals 1080 from the base station 1040 to the remote units 1020, 1030, and 1050 and reverse link signals 1090 from the remote units 1020, 1030, and 1050 to base stations 1040.

In FIG. 10, remote unit 1020 is shown as a mobile telephone, remote unit 1030 is shown as a portable computer, and remote unit 1050 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 10 illustrates remote units according to the teachings of the disclosure, the disclosure is not limited to these exemplary illustrated units. Aspects of the disclosure may be suitably employed in many devices which include MRAM circuitry.

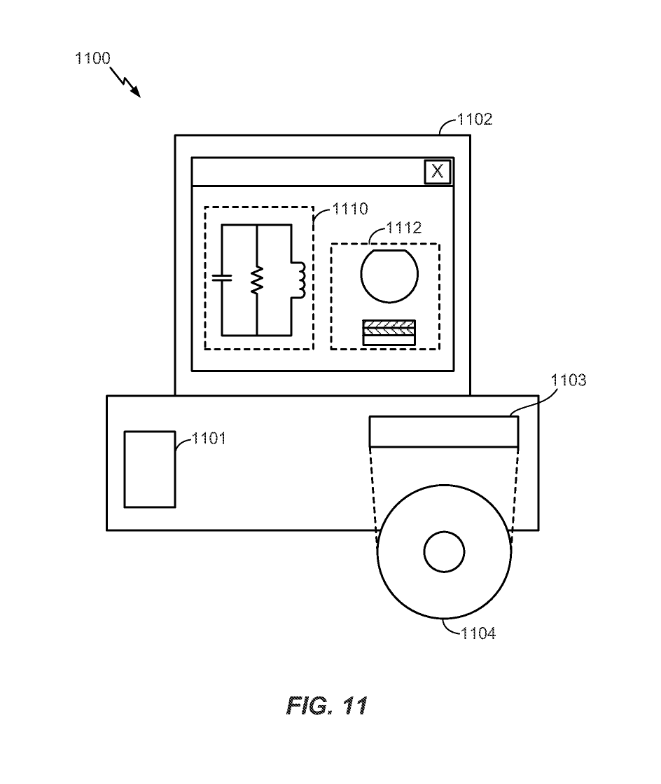

FIG. 11 is a block diagram illustrating a design workstation used for circuit, layout, and logic design of a semiconductor component, such as the MRAM circuitry disclosed above. A design workstation 1100 includes a hard disk 1101 containing operating system software, support files, and design software such as Cadence or OrCAD. The design workstation 1100 also includes a display 1102 to facilitate design of a circuit 1110 or a semiconductor component 1112 such as an MRAM circuitry. A storage medium 1104 is provided for tangibly storing the circuit design 1110 or the semiconductor component 1112. The circuit design 1110 or the semiconductor component 1112 may be stored on the storage medium 1104 in a file format such as GDSII or GERBER. The storage medium 1104 may be a CD-ROM, DVD, hard disk, flash memory, or other appropriate device. Furthermore, the design workstation 1100 includes a drive apparatus 1103 for accepting input from or writing output to the storage medium 1104.

Data recorded on the storage medium 1104 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1104 facilitates the design of the circuit design 1110 or the semiconductor component 1112 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A memory apparatus, comprising:
a first magnetic tunnel junction (MTJ) reference cell coupled to a reference node;
a first MTJ data cell coupled to a data node;
sense circuitry coupled to the reference node and the data node;
first write driver circuitry coupled to an input data path of the first MTJ data cell; and
switching circuitry configured for selectively coupling the first MTJ reference cell and/or the first MTJ data cell to the first write driver circuitry.

2. The apparatus of claim 1, further comprising:
in the first MTJ reference cell, a first reference MTJ coupled to the reference node and a second reference MTJ coupled to the reference node; and
in the first MTJ data cell, a first data MTJ coupled to the data node;

3. The apparatus of claim 2, in which at least one of the first reference MTJ and the second reference MTJ is programmable to either a parallel state or an anti-parallel state by signaling on the input data path.

4. The apparatus of claim 1, further comprising:
in the switching circuitry, a first reference select transistor coupled between the first MTJ reference cell and the first write driver circuitry, and a second reference select transistor coupled between the first MTJ reference cell and the first write driver circuitry; and
a first reference cell bit line coupled to the first reference select transistor and the second reference select transistor.

5. The apparatus of claim 1, further comprising:
in the switching circuitry, a first reference select transistor coupled between the first MTJ reference cell and the first write driver circuitry, and a second reference select transistor coupled between the first MTJ reference cell and the first write driver circuitry;
a first reference cell bit line coupled to the first reference select transistor; and
a second reference cell bit line coupled to the second reference select transistor.

6. The apparatus of claim 1, further comprising:
second write driver circuitry; and
the switching circuitry further configured for selectively coupling the first MTJ reference cell and/or a second MTJ data cell to the second write driver circuitry.

7. The apparatus of claim 6, further comprising:
in the switching circuitry, a first reference select transistor coupled between the first MTJ reference cell and the first write driver circuitry, and a second reference select transistor coupled between the first MTJ reference cell and the second write driver circuitry; and
a reference cell bit line coupled to the first reference select transistor and the second reference select transistor.

8. The apparatus of claim 6, further comprising:
a third MTJ data cell;
third write driver circuitry; and
the switching circuitry further configured to selectively couple the third MTJ data cell to the third write driver circuitry.

9. The apparatus of claim 1, further comprising:
a plurality of merged reference cells including the first MTJ reference cell coupled to the reference node.

10. The apparatus of claim 9, further comprising:
a fixed reference cell coupled to the reference node.

11. The apparatus of claim 1, integrated in a mobile phone, a set top box, a music player, a video player, an entertainment unit, a navigation device, a computer, a hand-held personal communication systems (PCS) unit, a portable data unit, and/or a fixed location data unit.

12. A method for configuring magnetic random access memory (MRAM) circuitry, comprising:
selectively coupling write driver circuitry to an MTJ reference cell in response to a reference select signal;
applying a first write current to program at least one reference MTJ in the MTJ reference cell;
selectively coupling the write driver circuitry to a first MTJ data cell in response to a write select signal; and
applying a second write current to program at least one data MTJ in the first MTJ data cell.

13. The method of claim 12, further comprising:
selectively coupling the write driver circuitry to a second MTJ data cell in response to a write select signal; and
applying a second write current to program at least one data MTJ in the second MTJ data cell.

14. The method of claim 12, further comprising integrating the MRAM circuitry into a mobile phone, a set top box, a music player, a video player, an entertainment unit, a navigation device, a computer, a hand-held personal communication systems (PCS) unit, a portable data unit, and/or a fixed location data unit.

15. A method for configuring magnetic random access memory (MRAM) circuitry, comprising steps of:
selectively coupling write driver circuitry to an MTJ reference cell in response to a reference select signal;
applying a first write current to program at least one reference MTJ in the MTJ reference cell;
selectively coupling the write driver circuitry to an MTJ data cell in response to a write select signal; and
applying a second write current to program at least one data MTJ in the MTJ data cell.

16. The method of claim 15, further comprising steps of:
selectively coupling the write driver circuitry to a second MTJ data cell in response to a write select signal; and
applying a second write current to program at least one data MTJ in the second MTJ data cell.

17. The method of claim 15, further comprising steps of: integrating the MRAM circuitry into a mobile phone, a set top box, a music player, a video player, an entertainment unit, a navigation device, a computer, a hand-held personal communication systems (PCS) unit, a portable data unit, and/or a fixed location data unit.

18. An apparatus for configuring magnetic random access memory (MRAM) circuitry, comprising:
means for selectively coupling write driver circuitry to an MTJ reference cell in response to a reference select signal;
means for applying a first write current to program at least one reference MTJ in the MTJ reference cell;
means for selectively coupling the write driver circuitry to a first MTJ data cell in response to a write select signal; and
means for applying a second write current to program at least one data MTJ in the first MTJ data cell.

19. The method of claim 18, further comprising:
means for selectively coupling the write driver circuitry to a second MTJ data cell in response to a write select signal; and
means for applying a second write current to program at least one data MTJ in the second MTJ data cell.

20. The apparatus of claim 18, integrated in a mobile phone, a set top box, a music player, a video player, an entertainment unit, a navigation device, a computer, a hand-held personal communication systems (PCS) unit, a portable data unit, and/or a fixed location data unit.
